(19) United States
(12) Patent Application Publication
(10) Pub. No.: US 2024/0210477 A1
(43) Pub. Date: Jun. 27, 2024

(54) BATTERY MANAGEMENT SYSTEM USING GRAPH NEURAL NETWORK

(71) Applicant: VOLKSWAGEN AKTIENGESELLSCHAFT, Wolfburg (DE)

(72) Inventors: Brett Dufford, Menlo Park, CA (US); Gianina Alina Negoita, San Leandro, CA (US); William A. Paxton, Redwood City, CA (US)

(21) Appl. No.: 18/086,236

(22) Filed: Dec. 21, 2022

(51) Int. Cl. G01R 31/367; G01R 31/392

(52) U.S. Cl. CPC G01R 31/367; G01R 31/392

(57) ABSTRACT

A battery management system, method, and apparatus for determining a state of health indication for a battery are provided. Battery data is observed for a battery. A usage profile for the battery is determined by applying a graph convolutional network on the battery data. A state of health is then determined based on the usage profile.

### Cross-reference to Related Applications

None.

### FIELD

The present disclosure relates to methods, apparatuses, and systems for a battery management system (BMS) and, more particularly, to a BMS that uses graph neural network and node clustering for battery usage profile generation.

### BACKGROUND

Attempts have been made to apply machine learning methods to take observable battery characteristics as input and then output a state of health (SoH) for that observed battery. The SoH is an indicator to quantify an aging level for a battery in terms of capacity fade and/or internal resistance. SoH estimation is crucial for improving battery life, understanding battery operation, and gaining increased performance from the battery.

The SoH can be generally estimated by experimental and model-based methods. Experimental methods monitor battery behaviors by analyzing the full cycle of experimental data of battery voltage, current, and temperature. Model-based estimation methods can be further divided into physical mechanism-based state estimation methods and data-driven methods.

While the battery SoH can be measured with sufficient accuracy from accelerated lab tests on the cell level, it is difficult to measure these quantities adequately at module/pack level in electric vehicles for representative driving and charging behavior in the real world. Even a simple task of a precise measurement of status of charge (SoC) for a battery is a challenge in current electric vehicles. Currently, a SoC estimation is only approximated by a discrete open circuit voltage lookup tables, where the lookup tables map the relationship from voltage (ideally in rest) to SoC. However, such mapping does not take into account hysteresis in degradation of the battery. Furthermore, the voltage-based measurement of SoC is impractical for batteries in electric vehicles that constantly experience repeated small loads for housekeeping functions (such as data acquisition and upload, temperature control, and/or load balancing) that leads to a quasi-closed circuit voltage that violates the open circuit voltage assumption.

In current battery management and control systems (BMS), battery degradation is not adequately represented by SoC or by SoH measurements due to limited real-time modeling experience as well as limited compute and memory capabilities for applying real time based estimation. Furthermore, battery degradation is a path dependent problem; that is, the state of health of a battery is dependent on the way that battery was used to that current point in time.

Therefore, in order to characterize battery degradation, it is important to develop new techniques that cluster batteries based on usage patterns. Once the batteries usage profiles are clustered into a distinct usage profile, the distinct usage profile can be taken into account for a more accurate battery state of health estimation.

### BRIEF DESCRIPTION OF THE FIGURES

The present disclosure is illustrated by way of example and not limitation in the figures of the accompanying drawings, in which like references indicate similar elements and in which:

FIG. 1 illustrates a flow chart for determining a state of health for a battery using an embodiment of the present disclosure;

FIG. 2 illustrates a block diagram of an architecture of an embodiment of the present disclosure to generate labels for battery usage;

FIG. 3 illustrates a flow chart of an embodiment of the present disclosure to determine a usage profile for a battery;

FIG. 4 illustrates a block diagram of an architecture of another embodiment of the present disclosure to generate labels for battery usage;

FIG. 5 illustrates a flow chart of another embodiment of the present disclosure to determine a usage profile for a battery;

FIG. 6 illustrates a block diagram for generating edges for a temporal adjacency matrix; and

FIG. 7 illustrates a simplified block diagram of a vehicle in accordance with an example embodiment of the present disclosure.

### DETAILED DESCRIPTION OF THE EMBODIMENTS

The figures and descriptions provided herein may have been simplified to illustrate aspects that are relevant for a clear understanding of the herein described devices, systems, and methods, while eliminating, for the purpose of clarity, other aspects that may be found in typical devices, systems, and methods. Those of ordinary skill in the art may recognize that other elements and/or operations may be desirable and/or necessary to implement the devices, systems, and methods described herein. Because such elements and operations are well known in the art, and because they do not facilitate a better understanding of the present disclosure, a discussion of such elements and operations may not be provided herein. However, the present disclosure is deemed to inherently include all such elements, variations, and modifications to the described aspects that would be known to those of ordinary skill in the art.

Battery degradation is a path dependent problem, i.e., the state of health of a battery is dependent on the way that battery has been used up until that current point in time. Therefore, in order to characterize electric vehicle (EV) battery degradation, it is beneficial to cluster batteries based on usage patterns. Once the batteries have been clustered into groups (also referred to as “profiles”), each group can be evaluated with the usage history taken into account, leading to a more accurate battery state of health estimation.

Clustering, generally, seeks to group data into sections where the intra-cluster similarity is higher than the inter-cluster similarity. While there are many methods and algorithms available to do this, deep learning may be leveraged to cluster data on abstract, high level features, and lead to more optimal clustering of the data.

In some embodiments of the present disclosure, a clustering method involves clustering the battery elective vehicle (BEV) driving and charging history into groups using a graph-based approach. While traditional clustering separates data based on the distance between data points, clustering on network graphs, also called community detection, offers a way to separate data based on edges that connect the nodes. Edges can be formed based on distance functions or something more abstract, such as the temporal relation of the data points. The method outlined herein seeks to leverage a novel neural network architecture to generate a graph representation of battery data sub-sequences based on both learned features and temporal relationships before finding a graph segmentation that maximizes modularity. Training this model in an end-to-end manner can allow the model to learn the optimal node embedding, graph representation, and graph segmentation to cluster the time-series data.

Once the battery data subsequences are clustered into profiles, the vehicle's usage history can be analyzed in this way to understand the usage patterns of that driver/vehicle. Additionally, an entire history of a battery EV (BEV) can be clustered based on the composition of profiles within that entire history. This can be a simpler problem, as the BEV history can be converted into a univariate sequence of labels, which can be clustered using less complex clustering methods.

In some embodiments, the proposed approach is graph based using an end-to-end trainable model. The neural network in this model can optimize what information is used to generate the network graph, as well as optimize the splitting of the graph into communities. Additionally, the architecture of the model can be modified to take into account the temporal relationship of the battery data, which may lead to better clustering.

In terms of use cases of some embodiments of the present disclosure, there are two potential applications for this model architecture. For instance, a two-stage clustering of the EV data can be performed through sub-sequence clustering. This methodology would involve first separating the EV history into sub-sequences of a set size (e.g., one calendar week, i.e., seven days). The model architecture proposed here would be used to label each subsequence, which would then be recombined in order to create a sequence of labels characterizing each battery's history. This sequence could then be analyzed using any number of methods. For example, the sequences can be analyzed to determine the change in cluster labels, and therefore battery usage profiles, for months or seasons to understand vehicle usage variations over time. Additionally, the sequence of labels can be clustered to separate batteries into groups that have seen similar use across their whole life. This clustering can be done using less computationally complex algorithms, as the sequences would now be univariate and much less complex than the original battery data histories.

Also, the use of a recurrent neural network (e.g., LSTM or GRU encoder) allows for the architecture in some embodiments to be applied to entire battery histories without worrying about varying time series lengths for the corresponding batteries. This can result in each graph node representing a battery, and the label representing the cluster to which that battery belongs. The clustering can be performed based on the driving and charging history of the corresponding vehicle, but the results would not be as interpretable as it would be for the sub-sequence approach.

In addition to applications of this architecture to clustering, it is possible the model could be applied to other tasks as well, such as forecasting. For example, given the history of a vehicle expressed as a sequence of node labels, the future vehicle usage could be forecast as a continuing sequence of labels. If each label was mapped to a representative battery damage “cost”, this could be enough information to predict the end of the batteries usable life, without needing to predict each variable in the multivariate set independently.

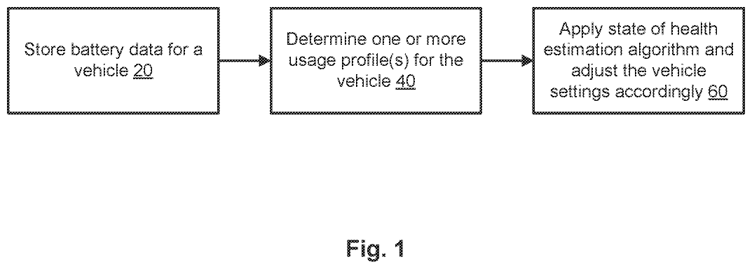

Now turning to the figures, FIG. 1 illustrates a flow chart for determining a state of health for a battery using an embodiment of the present disclosure. In some embodiments, a vehicle can have an electric battery to power an electric powertrain of the vehicle. Battery data for the electric battery can be stored for analysis. Battery data can include amount of energy draw to power the powertrain and/or other vehicle electronics, amount of braking regeneration, amount of charging the battery, amount of discharging the battery, charging speed of the battery, when and where the vehicle is physically located, battery temperature, activation of a battery cooling system, state of charge, state of health, depth of discharge, other battery parameters and characteristics, and combinations thereof. The battery data can be stored in a data storage of the vehicle (e.g., in a battery management system of the vehicle or another storage device of the vehicle) or remotely (e.g., in cloud storage) 20. One or more types of the battery data can be selected as features for a model of the present disclosure.

Select features from the battery data can be preprocessed and feature engineered for input into a deep neural network for clustering of the battery of the vehicle into one or more usage profiles 40. Once the usage profile(s) are determined, a state of health estimation algorithm can be applied for that specific usage profile(s) to generate a SoH estimation 60. Once a SoH estimation is determined, vehicle settings can be adjusted accordingly to be specific to the current SoH estimation. For instance, if the SoH estimation reflects that the battery has degraded to 80% of its initial max capacity, then the vehicle's maximum range when the battery is full can likewise be reduced to 80% of the original maximum range.

Once usage profiles are established, SOH estimation can be performed using one of several methods. If ground truth data is available for the battery degradations, e.g., through an internal resistance or capacity degradation measurement, then the average decrease in health associated with each profile can be determined. This average health can be mapped to the past and forecasted battery profiles to determine both past and future battery degradation. If ground truth data is not available, the usage profiles can be run through a simulation or lab test to evaluate their impact of SOH.

In some embodiments where the ground truth data is available, once usage profiles for each electric vehicle battery are determined, agglomerative clustering can be applied on top of the labeled usage profiles to cluster vehicles (referred to by “vehicle identification numbers” or “VINs”) into groups. A recurrent neural network or a transformer can be trained for each cluster to use history data and forecast SoH. Input to this model can be the established features, SoH values from the past and predicted SoH values for the future.

In some embodiments where ground truth data is not available, once usage profiles for each electric vehicle battery are determined, agglomerative clustering can be applied on top of labeled usage profiles to cluster VINs into groups. Once a cluster of VINs are established, an LSTM-based auto-encoder is trained for each cluster on healthy initial data. A reconstruction error can be used at inference time to come up with a battery health index for each time series scenario. Alternatively, an associated health penalty cost can be assigned for each battery usage label and use a simple algorithm to aggregate health penalty cost information over time to come up with degradation cost assuming batteries start at 100% state of health at zero usage.

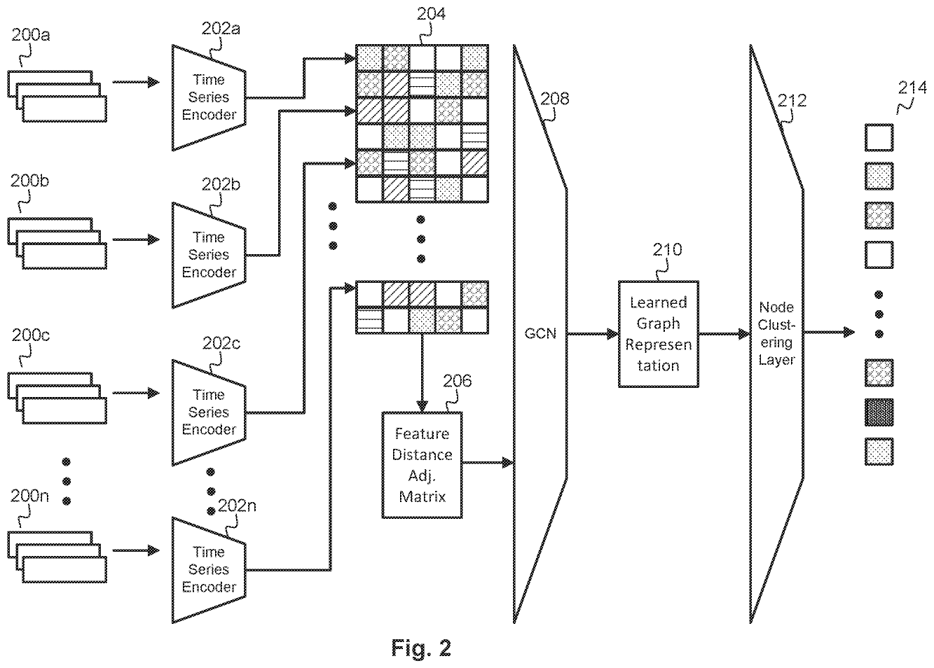

FIG. 2 illustrates a block diagram of an architecture of an embodiment of the present disclosure to generate labels for battery usage. In some embodiments, battery data 200a-200n from one or more vehicles can be inputted into time series encoders 202a-202n to generate node representations 204. For instance, the battery data 200a for vehicle 1 is partitioned into week segments and then inputted to the time series encoder 202a. The output of the time series encoder 202a is used to populate one or more rows of the node representations 204.

Likewise, the battery data 200b for vehicle 2 is also partitioned into week segments and then inputted to the time series encoder 202b. The output of the time series encoder 202b is used to populate one or more rows of the node representations 204.

The battery data 200c for vehicle 3 can be partitioned into month segments and then inputted to the time series encoder 202c. The output of the time series encoder 202c is used to populate one or more rows of the node representations 204.

The battery data 200n for vehicle n is partitioned into week segments and then inputted to the time series encoder 202n. The output of the time series encoder 202n is used to populate one or more rows of the node representations 204.

Each of the vehicle 1-n′s battery history can be of variable length. For instance, the vehicle 2 can have battery data 200b which goes back 6 months, giving 24 subsequent 1-week segments, while the vehicle 1 may have 6 weeks of battery history, giving only 6 subsequent 1-week segments. The vehicle n can be the entire battery history of the vehicle. In some embodiments, the selected battery data 200a-200n can include mileage of the respective vehicle, if the respective vehicle is at home or not at home, external temperature of the respective vehicle, state of charge of the respective vehicle, and other telematics data from the vehicle.

The time series encoders 202a-202n can be expanded in number to provide for an n number of vehicles for converting such battery data from those vehicles into the node representations 204. It can be appreciated that the span of the subsequences for each vehicle can be a predefined time period in the order of days, weeks, months, years, or fractions thereof.

The time series encoders 202a-202n can transform each subsequence of battery data to entries of the node representations 204. This layer serves as a method of feature reduction and as a compression tool to create the node representations for each multivariate time series subsequence. As a learnable layer, the model can update the encodings throughout the training process, adapting the node representations to contain the information most relevant to the separation of time series subsequences into clusters. This layer will convert the N multivariate subsequences into an N×M matrix, where M is the number of features output from the time series encoder. This is a hyperparameter that can be tuned during model development.

The time series encoders 202a-202n can be an LSTM, GRU layer, or other recurrent neural network, which are effective at analyzing and extracting data from pre-segmented time series subsequences. Furthermore, use of an LSTM or GRU can enable sequences of varying length to be used. In the case of EV driving data, this means the model could be fed multivariate weeks from each vehicle or entire driving histories for one or more vehicles.

For instance, the battery data 200a for the vehicle 1 can have 3,000 data points covering five battery data fields/features. The time series encoder 202a transforms the battery data 200a into a row on the matrix 204 with five columns, where each columns is for a particular feature.

The row of the node representations 204 can be transformed into a single node in the feature distance adjacency matrix 206. Edges for the nodes of the feature-distance adjacency matrix (FDAM) are calculated using a node distance function. The feature-distance adjacency matrix stores the initial edges for generating a corresponding feature distance adjacency graph. In some embodiments, a k-nearest neighbor graph can be used to generate edges between the closest k nodes to each node in the encoded representation. It can be appreciated that other distance functions can be used as well to form the edges for the graph.

The FDAM 206 is inputted to a graph convolutional network (GCN) 208. The graph convolution layer enables the analysis of graph-structured data in a learnable neural network. While the initial graph representation corresponding to the FDAM 206 acts as a seed, this layer of the GCN can learn to modify the nodes and edges in order to create a more effective representation for clustering. In particular, the GCN 208 can process and learn the graph and create an adapted representation of the graph using parameter adjustment during the end-to-end training of the model. The relevant features can then be extracted from feature distance adjacency matrix 206 by the GCN 208 for clustering.

The GCN 208 outputs a learned graph representations 210, which is further inputted to a node clustering layer 212 to generate clusters 214 (or otherwise referred to as labels or groups). The node clustering layer 212 takes the learned graph representation 210 as an input, and outputs cluster labels 214 for each node (each subsequence). A loss function can be applied to the entire model to maximize modularity. Implementing this loss as a differentiable function based on graph clustering with graph neural networks enables end-to-end learning.

Furthermore, each cluster can be associated to a particular battery usage profile. The clustering algorithm assigns a label to each time series sample, but by taking the mean or median of all samples assigned the same label, a load profile representing that cluster can be created. For instance, once the subsequences are clustered for the VINs, labels can be assigned to each subsequence for each VIN. For each assigned label, the features are known for that particular subsequence as time series. An average over all weeks (or other time length) can be taken that belong in that label category, i.e., the data points are averaged for the time series subsequences to obtain an averaged representative profile for that particular label.

For instance, in some embodiments, a SoC mean line is plotted for a mean of the SoC time series samples for a state of charge percentage feature over time (e.g., days, weeks, etc.). The SoC mean line provides an SOC profile for this cluster. Similarly for other features (e.g., depth of discharge per cycle, typical charging energy input per cycle, etc.), a feature mean line can be found and define the corresponding cluster. Each of the usage profiles can correspond to particular behaviors including batteries that are often fast charged, batteries that rarely fall below 70% capacity, or other identifiable patterns. In some embodiments, the profiles can also correspond to unknown patterns that are flagged by the model of the present disclosure.

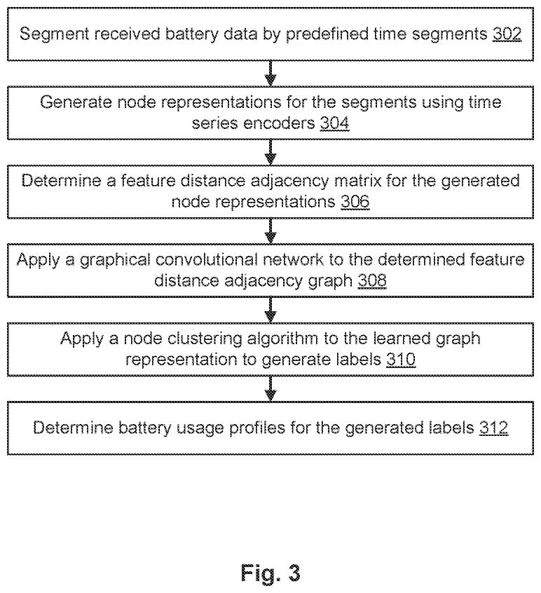

FIG. 3 illustrates a flow chart of an embodiment of the present disclosure to determine a usage profile for a battery. In some embodiments, received battery data is segmented into subsequences using a predefined time segment 302 (e.g., a day, week, month, year, etc.). The subsequences are transformed into node representations using time series encoders 304. A feature distance adjacency matrix is determined for the node representations using a feature distance algorithm 306. A graphical convolutional network is applied to the FDAM to generate a learned graph representation 308. Next, a node clustering algorithm is applied to the learned graph representation to generate labels for the subsequences 310. One or more usage profiles are determined for the labels 312.

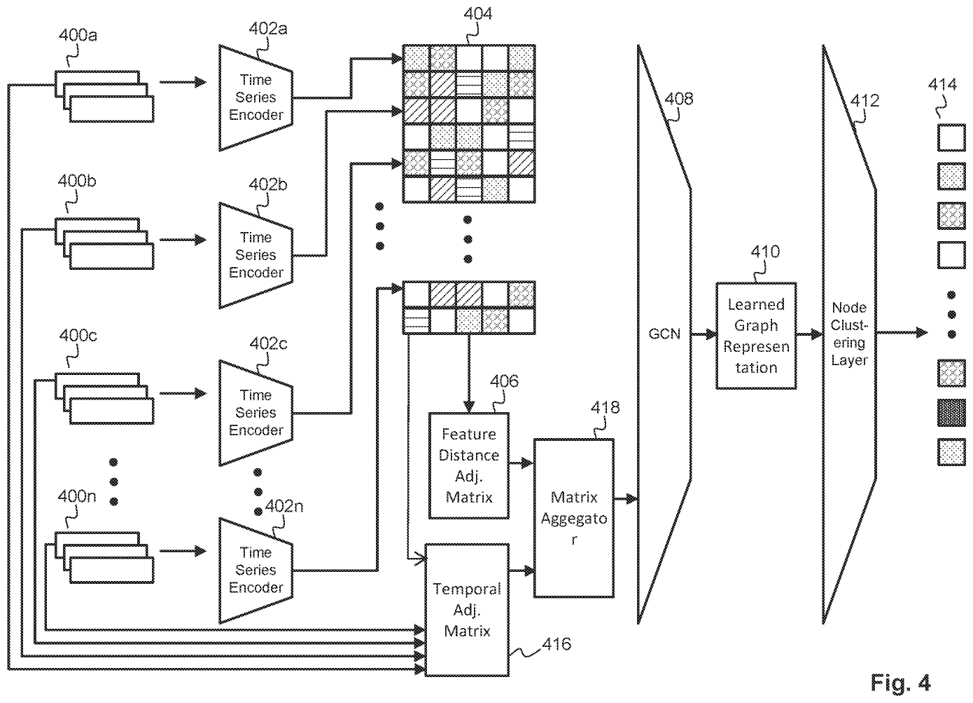

FIG. 4 illustrates a block diagram of an architecture of another embodiment of the present disclosure to generate labels. In some embodiments, subsequent segments 400a-400n are inputted to time series encoders 402a-402n and used to provide timing information for a temporal adjacency matrix (TAM) 416. The time series encoders 402a-402n populate rows and columns of node representations 404. Next, the node representations 404 are transformed into a feature distance adjacency matrix 406 using a feature distance algorithm. These steps are similar to the steps illustrated in FIG. 2 for generating such matrix. Edges for the additional temporal adjacency matrix 416 is generated by forming edges for temporally neighboring nodes of the FDAM. Moreover, the node representations 404 are also transformed into a temporal adjacency matrix 416 using time order information. Edges for the additional temporal adjacency matrix 416 is generated by forming edges for temporally neighboring nodes of the FDAM.

Corresponding graphs for the FDAM 406 and the TAM 416 are combined by a graph aggregator 418. The combined graph is then inputted to a GCN 408 to generate a learned graph representation 410 for the combined graphs. The combination of the temporal adjacency graph and the feature adjacency graph can be done in multiple ways.

In other embodiments, the matrix aggregator 418 can be omitted and the corresponding graphs to the FDAM 406 and the TAM 416 can be inputted directly to the GCN 408. For instance, the graphs are each fed into a separate layer of the GCN 408 and then summed at the outputs of these layers. This would allow the model to learn the relative weights that each component graph should have in the final learned graph representation. If some or all of the temporal information is more important than the feature information, then it could be represented through heavier weighting of the temporal edges.

Alternatively, in some embodiments, the feature distance adjacency graph and the temporal adjacency graph can be concatenated before input to the GCN 408.

Referring back to FIG. 4, the learned graph representation 410 is inputted to a node clustering layer 412 to generate clusters 414. As discussed above, battery usage profiles can then be assigned to the clusters.

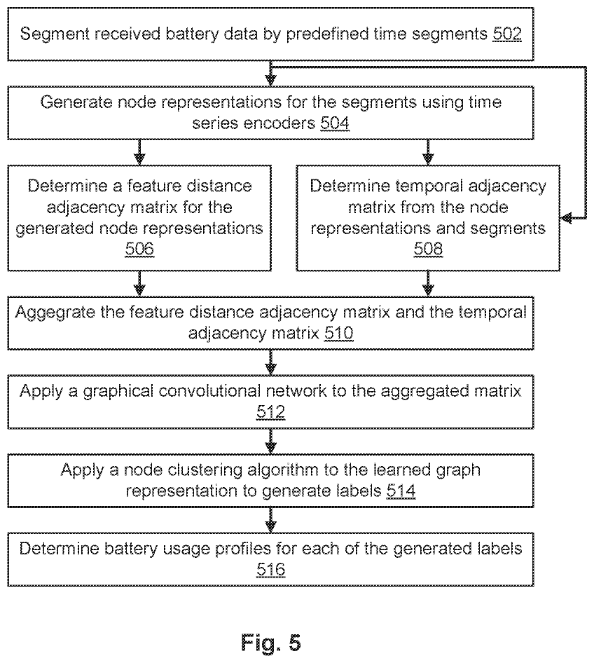

FIG. 5 illustrates a flow chart of another embodiment of the present disclosure to determine a usage profile for a battery. In some embodiments, received battery data is segmented into subsequences using a predefined time segment 502 (e.g., a day, week, month, year, etc.). The subsequences are transformed into node representations using time series encoders 504. The node representations can be an N×M matrix. A feature distance adjacency matrix is determined from the node representations using a feature distance algorithm 506. Additionally, a temporal adjacency matrix is determined from the node representations and the subsequences 508. The feature distance adjacency matrix and the temporal adjacency matrix are aggregated 510. A graph convolutional network is applied to the aggregated matrix to generate a learned graph representation 512. Next, a node clustering algorithm is applied to the learned graph representation to generate labels 514. Specific usage profiles can be determined for the generated labels 516.

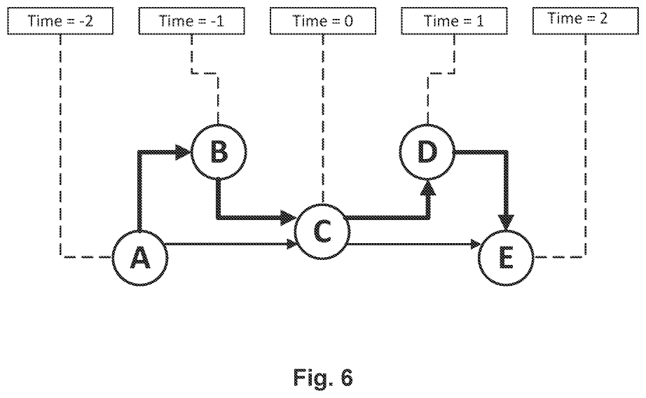

FIG. 6 illustrates a block diagram for generating edges for a temporal adjacency matrix. A corresponding graph for the temporal adjacency matrix allows the downstream model to have information about the relation of the multivariate time series subsequences, instead of treating them as strictly independent. The temporal adjacency graph has the same nodes as a corresponding feature-distance adjacency graph, with the same encoded node representations. However, instead of the edges representing similarity of the time series features, the edges represent the proximity in time to one another. There are varying ways this can be achieved. An implementation can be to create edges between a node and the sequences immediately before and after that node, essentially making a single chain of nodes ordered by time. However, weighted edges can also be used to create edges of different weight representing how far the subsequences are away from each other in time.

For instance, referring to FIG. 6, node A represents the subsequence of the battery data at time −2; node B represents the subsequence of the battery data at time −1; node C represents the subsequence of the battery data at time −0; node D represents the subsequence of the battery data at time 1; and node E represents the subsequence of the battery data at time 2.

Node B and Node D are immediately in time before and after node C, so they are connected to C with a higher-weighted line/edge. The arrow direction of the lines represent the directional flow of time. Node A and node E are two time units away from node C in time, so they have lower-weighted line/edge.

In this way, edges for the TAM can be formed for the nodes. A corresponding graph to the TAM can also be generated using this edge information for use by a GCN.

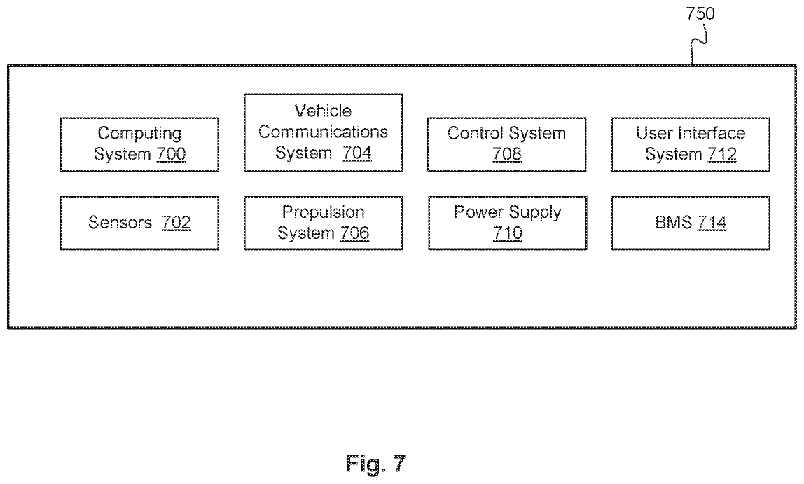

FIG. 7 illustrates a simplified block diagram of a vehicle in accordance with an example embodiment of the present disclosure. In an example embodiment, a vehicle 750 comprises a computing system 700, sensors 702, a vehicle communications system 704, a propulsion system 706, a control system 708, a power supply 710, a user interface system 712, and a battery management system 714. In other embodiments, the vehicle 750 may include more, fewer, and/or different systems, and each system may include more, fewer, and/or different components. Additionally, the systems and/or components may be combined and/or divided in a number of arrangements.

The computing system 700 may be configured to transmit data to, receive data from, interact with, and/or control one or more of the propulsion system 706, the sensors 702, the control system 708, BMS 714, and any other components of the vehicle 750. The computing system 700 may be communicatively linked to one or more of the sensors 702, vehicle communications system 704, propulsion system 706, control system 708, power supply 710, user interface system 712, and BMS 714 by a system bus (e.g., CAN bus, Flexray, etc.), a network (e.g., via a vehicle-to-vehicle, vehicle-to-infrastructure, vehicle-to-device, and so on), and/or other connection mechanism.

In at least one embodiment, the computing system 700 may be configured to store data in a local data storage and/or communicatively coupled to an external data storage. It can be appreciated that the data can also be transmitted to a cloud service and received from the cloud service via over-the-air (OTA) wireless techniques. For instance, OTA wireless technique can be used to transmit updated DNN models or to upload interesting data such as corner cases.

In another embodiment, the computing system 700 may be configured to cause the sensors 702 to capture images of the surrounding environment of the vehicle 750. In yet another embodiment, the computing system 700 may control operation of the propulsion system 706 to autonomously or semi-autonomously operate the vehicle 750. As yet another example, the computing system 700 may be configured to store and execute instructions corresponding to an algorithm (e.g., for steering, braking, and/or throttling) from the control system 710. As still another example, the computing system 700 may be configured to store and execute instructions for determining the environment around the vehicle 750 using the sensors 702. Even more so, the computing system 700 may be configured to store and execute instructions for operating the BMS 714. The BMS 714 and/or computing system 700 can sense and record battery characteristics including, temperature, voltage, and current, via the CAN data every predefined number of hours and/or days.

A deep neural network (DNN), running on the computing system 700, BMS 714, and/or remotely in the cloud (not shown) can use this information to apply the present disclosure to generate a usage profile for the battery. The usage profile can them be applied to a SoH DNN specific for that usage profile to generate a SoH indication for the battery. Based on the generated SoH indication, user feedback can be provided the user of the vehicle valuable direction to preserve the SoH of the battery (e.g., do not perform three fast charges in a row). These are just a few examples of the many possible configurations of the computing system 700.

The computing system 700 can include one or more processors. Furthermore, the computing system can have its own data storage and/or use an external data storage. The one or more processors may comprise one or more general-purpose processors and/or one or more special-purpose processors. To the extent the processor includes more than one processor, such processors could work separately or in combination. Data storage of the computing system 700, in turn, may comprise one or more volatile and/or one or more non-volatile storage components, such as optical, magnetic, and/or organic storage. The data storage may be integrated in whole or in part with the one or more processors of the computing system 700 and may be communicatively coupled to the data storage. In some embodiments, data storage of the computing system 700 may contain instructions (e.g., program logic) executable by the processor of the computing system 700 to execute various vehicle functions (e.g., the methods disclosed herein).

The term computing system may refer to data processing hardware, e.g., a CPU and/or GPU, and encompasses all kinds of apparatus, devices, and machines for processing data, including by way of example a programmable processor, a computer, multiple processors, computers, cloud computing, and/or embedded low-power devices (e.g., Nvidia Drive PX2). The system can also be, or further include, special purpose logic circuitry, e.g., an FPGA (field programmable gate array) or an ASIC (application-specific integrated circuit). The system can optionally include, in addition to hardware, code that creates an execution environment for computer programs, e.g., code that constitutes processor firmware, a protocol stack, a database management system, an operating system, or a combination of one or more of them. A computer program can also be used to emulate the computing system.

A computer program which may also be referred to or described as a program, (software, a software application, an app, a module, a software module, a script, or code) can be written in any form of programming language, including compiled or interpreted languages, or declarative or procedural languages, and it can be deployed in any form, including as a stand-alone program or as a module, component, subroutine, or other unit suitable for use in a computing environment. A computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

The processes and logic flows described in this specification can be performed by one or more programmable computers executing one or more computer programs to perform functions by operating on input data and generating outputs. The processes and logic flows can also be performed by special purpose logic circuitry, e.g., an FPGA or an ASIC, or by a combination of special purpose logic circuitry and one or more programmed computers.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include wired and/or wireless local area networks (LANs) and wired and/or wireless wide area networks (WANs), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

The sensors 702 may include a number of sensors configured to sense information about an environment in which the vehicle 750 is located, as well as one or more actuators configured to modify a position and/or orientation of the sensors. The sensors can include a global positioning system (GPS), an inertial measurement unit (IMU), a RADAR unit, a laser rangefinder and/or one or more LIDAR units, and/or a camera. In some embodiments, the sensors 702 may be implemented as multiple sensor units each mounted to the vehicle in a respective position (e.g., top side, bottom side, front side, back side, right side, left side, etc.). Other sensors are possible as well.

The vehicle communications system 704 may be any system communicatively coupled (via wires or wirelessly) to one or more other vehicles, sensors, or other entities, either directly and/or via a communications network. The wireless communication system 704 may include an antenna and a chipset for communicating with the other vehicles, sensors, servers, and/or other entities either directly or via a communications network. The chipset or wireless communication system 704 in general may be arranged to communicate according to one or more types of wireless communication (e.g., protocols) such as BLUETOOTH, communication protocols described in IEEE 802.11 (including any IEEE 802.11 revisions), cellular technology (such as V2X, V2V, GSM, CDMA, UMTS, EV-DO, WiMAX, or LTE), ZIGBEE, dedicated short range communications (DSRC), and radio frequency identification (RFID) communications, among other possibilities. The wireless communication system 704 may take other forms as well.

The propulsion system 706 may be configured to provide powered motion for the vehicle 750. The propulsion system 706 may include various components to provide such motion, including an engine/motor, an energy source, a transmission, and wheels/tires. The engine/motor may include any combination of an internal combustion engine, an electric motor (that can be powered by an electrical battery, fuel cell, and/or other energy storage device), and/or a steam engine. Other motors and engines are possible as well.

The control system 708 may be configured to control operation of the vehicle 750 and its components. The control system 708 may include various components, including a steering unit, a throttle, a brake unit, a perception system, a navigation or pathing system, and an obstacle avoidance system.

A perception system may be any system configured to process and analyze images and/or sensor data captured by the sensors (e.g., a camera, RADAR and/or LIDAR) of the vehicle 750 in order to identify objects and/or features in the environment in which the vehicle 750 is located, including, for example, traffic signals and obstacles. To this end, the perception system may use an object recognition algorithm, a structure-from-motion (SFM) algorithm, video tracking, or other computer vision techniques. In some embodiments, the perception system may additionally be configured to map the environment, track objects, estimate the speed of objects, etc.

In at least one embodiment, the overall system can comprise a perception subsystem for identifying objects, a planning subsystem for planning a smooth driving path around the obstacles, and a control subsystem for executing the path from the planner.

The power supply 710 may be a source of energy that powers the engine/motor of the vehicle 750 in full or in part and/or powers the electrical equipment of the vehicle 750. The engine/motor of the vehicle may be configured to convert the power supply 710 into mechanical energy. Examples of energy sources for the power supply 710 include gasoline, diesel, propane, other compressed gas-based fuels, ethanol, solar panels, batteries, and other sources of electrical power. The energy source(s) may additionally or alternatively include any combination of fuel tanks, batteries, capacitors, and/or flywheels. In some embodiments, the energy source may provide energy for other systems of the vehicle 750 as well.

In an embodiment, the power supply 710 is an electric battery that is communicatively coupled to the BMS 714. The BMS 714 monitors the various characteristics of the power supply 710, including battery temperature, battery voltage, battery current, and battery charging and discharging data. This information can be stored locally by the BMS 714 and/or by the computing system 700. The BMS 714 can also transmit such monitored information via the vehicle communications system 704 to an external storage device (e.g., in the cloud). The BMS 714 may regulate the operating conditions of the power supply 710, e.g., cooling the battery temperature to within a predefined threshold temperature.

The computing system 700 can be configured to generate a usage profile using embodiments of the present disclosure. The SoH indication can be inputted to the BMS 714 for the BMS 714 to adjust the operating conditions of the power supply 710. In another embodiment, the usage profile generation algorithms of the present disclosure and SoH estimation based on the usage profile can be performed by one or more processors of the BMS 714.

The user interface system 712 may include software, a human-machine interface (HMI), and/or peripherals that are configured to allow the vehicle 750 to interact with external sensors, other vehicles, external computing devices, and/or a user. To this end, the peripherals may include, for example, a wireless communication system, a touchscreen, a microphone, and/or a speaker. The SoH indication or related metric (e.g., SoC) can be displayed via the user interface system 712.

In some embodiments, the vehicle 750 may include one or more elements in addition to or instead of those shown. For example, the vehicle 750 may include one or more additional interfaces and/or power supplies. Other additional components are possible as well. In such embodiments, the data storage of the computing system 700 may further include instructions executable by the processor of the computing system 700 to control and/or communicate with the additional components.

Still further, while each of the components and systems are shown to be integrated in the vehicle 750, in some embodiments, one or more components or systems may be removably mounted on or otherwise connected (mechanically or electrically) to the vehicle 750 using wired or wireless connections.

While the functionality of the disclosed embodiments and the system components used to provide that functionality have been discussed with reference to specific terminology that denotes the function to be provided, it should be understood that, in implementation, the component functionality may be provided, at least in part, components present and known to be included in conventional transportation vehicles.

For example, as discussed above, disclosed embodiments use software for performing functionality to enable measurement and analysis of data, at least in part, using software code stored on one or more non-transitory computer readable mediums running on one or more processors in a transportation vehicle. Such software and processors may be combined to constitute at least one controller coupled to other components of the transportation vehicle to support and provide autonomous and/or assistive transportation vehicle functionality in conjunction with vehicle navigation systems, and multiple sensors. Such components may be coupled with the at least one controller for communication and control via a CAN bus of the transportation vehicle or other busses (e.g., Flexray).

It should further be understood that the presently disclosed embodiments may be implemented using dedicated or shared hardware included in a transportation vehicle. Therefore, components of the module may be used by other components of a transportation vehicle to provide vehicle functionality without departing from the scope of the present disclosure.

Exemplary embodiments are provided so that this disclosure will be thorough, and will fully convey the scope to those who are skilled in the art. Numerous specific details are set forth, such as examples of specific components, devices, and methods, to provide a thorough understanding of embodiments of the present disclosure. In some illustrative embodiments, well-known processes, well-known device structures, and well-known technologies are not described in detail.

Terminology has been used herein for the purpose of describing particular illustrative embodiments only and is not intended to be limiting. The singular form of elements referred to above may be intended to include the plural forms, unless the context indicates otherwise. The method steps, processes, and operations described herein are not to be construed as necessarily requiring their performance in the particular order discussed or illustrated, unless specifically identified as an order of performance or a particular order is inherently necessary for embodiment to be operational. It is also to be understood that additional or alternative steps may be employed.

Disclosed embodiments include the methods described herein and their equivalents, non-transitory computer readable media programmed to carry out the methods and a computing system configured to carry out the methods. Further, included is a vehicle comprising components that include any of the methods, non-transitory computer readable media programmed to implement the instructions or carry out the methods, and systems to carry out the methods. The computing system, and any sub-computing systems, will typically include a machine-readable storage medium containing executable code; one or more processors; memory coupled to the one or more processors; an input device, and an output device connected to the one or more processors to execute the code. A machine-readable medium may include any mechanism for storing or transmitting information in a form readable by a machine, such as a computer processor. The information may be stored, for example, in volatile or non-volatile memory. Additionally, embodiment functionality may be implemented using embedded devices and online connection to cloud computing infrastructure available through radio connection (e.g., wireless communication) with such infrastructure.

It can be appreciated that embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively, or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain some cases, multitasking and parallel processing may be advantageous.

What is claimed is:

1. A computing system, comprising:
at least one data storage configured to store computer program instructions; and
at least one processor communicatively coupled to the at least one data storage,
the at least one processor is configured to execute the computer program instructions to perform the following, comprising:
receiving battery data for at least one battery;
determining at least one usage profile for the at least one battery based on the battery data using a graph convolutional network; and
providing a state of health (SoH) for the at least one battery based on the at least one usage profile.

2. The computing system of claim 1 wherein the determining the at least one usage profile step, further comprises the sub-steps of:
segmenting the received battery data into subsequences;
generating node representations for the subsequences using at least one time series encoder;
determining a feature-distance adjacency matrix (FDAM) for the node representations;
generating a learned graph representation by applying a graph convolutional network (GCN) on a corresponding graph to the feature-distance adjacency matrix; and
generating one or more labels from the learned graph representation by using a node clustering layer; and
determining the at least one usage profile of the at least one battery based on the one or more generated labels.

3. The computing system of claim 2 wherein each of the subsequences is a predefined time period.

4. The computing system of claim 3 wherein the predefined time period is one calendar day, week, month, or year.

5. The computing system of claim 1 wherein the time series encoder is long short-term memory neural network or a gated recurrent units network.

6. The computing system of claim 2 wherein in the determining the feature-distance adjacency matrix step further comprises, determining a temporal adjacency matrix (TAM) based on timing information from the subsequences and the node representations.

7. The computing system of claim 6 wherein edges for the TAM are formed for temporally proximate nodes of the node representations using timing data from the subsequences.

8. The computing system of claim 6 wherein in the generating the learned graph representation step, further comprising the sub-steps of:
combining the FDAM and TAM into an aggregated matrix; and
applying the GCN on a corresponding graph to the aggregated matrix to generate the learned graph representation.

9. The computing system of claim 8 wherein in the combining step, the FDAM and the TAM are combined by concatenating the FDAM and TAM.

10. The computing system of claim 1 wherein the at least one data storage and the at least one processor are embedded in a battery management system of a vehicle.

11. The computing system of claim 1 further comprising a computer network, wherein the at least one data storage and the at least one processor are embedded in a cloud computing environment and wherein the cloud environment is communicatively coupled to the at least one battery via the computer network.

12. A computer-implemented method for determining a state of heath for a battery, comprising the steps:
receiving battery data for at least one battery;
segmenting the received battery data into subsequences;
generating node representations for the subsequences using at least one time series encoder;
determining a feature-distance adjacency matrix (FDAM) for the node representations;
generating a learned graph representation by applying a graph convolutional network (GCN) on a corresponding graph to the feature-distance adjacency matrix;
generating one or more labels from the learned graph representation by using a node clustering layer; and
determining the at least one usage profile of the at least one battery based on the one or more generated labels.
; and
providing a state of health (SoH) for the at least one battery based on the at least one usage profile.

13. The computer-implemented method of claim 12 wherein each of the subsequences is a predefined time period.

14. The computer-implemented method of claim 13 wherein the predefined time period is one calendar day, week, month, or year.

15. The computer-implemented method of claim 12 wherein the time series encoder is long short-term memory neural network or a gated recurrent units network.

16. The computer-implemented method of claim 12 wherein in the determining the feature-distance adjacency matrix step further comprises, determining a temporal adjacency matrix (TAM) based on timing information from the subsequences and the node representations.

17. The computer-implemented method of claim 16 wherein edges for the TAM are formed for temporally proximate nodes of the node representations using timing data from the subsequences.

18. The computer-implemented method of claim 16 wherein in the generating the learned graph representation step, further comprising the sub-steps of:
combining the FDAM and TAM into an aggregated matrix; and
applying the GCN on a corresponding graph to the aggregated matrix to generate the learned graph representation.

19. The computer-implemented method of claim 18 wherein in the combining step, the FDAM and the TAM are combined by concatenating the FDAM and TAM.

20. A non-transitory computer readable medium encoded with instructions that when executed by at least one processor causes the processor to carry out the following operations:
receiving battery data for at least one battery;
segmenting the received battery data into subsequences;
generating node representations for the subsequences using at least one time series encoder;
determining a feature-distance adjacency matrix (FDAM) for the node representations;
generating a learned graph representation by applying a graph convolutional network (GCN) on a corresponding graph to the feature-distance adjacency matrix;
generating one or more labels from the learned graph representation by using a node clustering layer; and
determining the at least one usage profile of the at least one battery based on the one or more generated labels; and
providing a state of health (SoH) for the at least one battery based on the at least one usage profile.
